(19) United States
(12) Patent Application Publication
(10) Pub. No.: US 2010/0176405 A1
(43) Pub. Date: Jul. 15, 2010

(54) Light Emitting Diode Lighting Package with Improved Heat Sink

(75) Inventor: Russell G. Villard, Apex, NC (US)

Correspondence Address: PRIEST & GOLDSTEIN PLLC, 5015 SOUTHPARK DRIVE, SUITE 230, DURHAM, NC, 27713-7736, US

(73) Assignee: Cree, Inc., Durham, NC (US)

(21) Appl. No.: 12/729,923

(22) Filed: Mar. 23, 2010

Related U.S. Application Data
(63) Continuation of application No. 11/379,726, filed on Apr. 21, 2006, now abandoned.

(51) Int. Cl. H01L 33/64

(52) U.S. Cl. 257/88; 257/E33.075

(57) ABSTRACT

Improved lighting packages are described for light emitting diode (LED) lighting solutions having a wide variety of applications which seek to balance criteria such as heat dissipation, brightness, and color uniformity. The present approach includes a backing of thermally conductive material. The backing includes a cell structure. The cell structure comprises a plurality of hollow cells contiguously positioned in a side by side manner. The present approach also includes an array of LEDs. The array of LEDs is mounted to a printed circuit board (PCB). The PCB is attached to the cell structure to balance heat dissipation and color uniformity of the LEDs.

### FIELD OF THE INVENTION

The present invention relates generally to improvements in the field of light emitting diode (LED) lighting fixtures, and, in particular, to methods and apparatus for improving the heat dissipation of LED lighting fixtures.

### BACKGROUND OF THE INVENTION

As illustrated by FIGS. 1A, 1B and 1C, a common prior art LED mounting arrangement results in a substantial portion of the light output going upwardly in the direction of a normal to the top surface of a semiconductor photonic chip 12 as seen in FIG. 1B. As seen in FIG. 1A, a top view of an LED 10, the semiconductor photonic chip 12 is mounted on a substrate 14 which is in turn mounted on a bonding pad 16. The chip 12 is encapsulated beneath an optical lens 18 which focuses the light emitted by the chip 12.

FIG. 1B shows a side view of LED 10 with a plurality of light rays relative to a normal, N, to the top surface of chip 12 illustrating the light emitted by chip 12 as it passes out of lens 18. LED 10 is an XLamp™ 7090 from Cree, Incorporated.

FIG. 1C shows an illustrative plot of the light emitted by LED 10 with the y-axis representing the intensity, I, and the x-axis representing the angle, θ, of the emitted light with respect to the normal, N, of FIG. 1B. As illustrated in FIG. 1C, a substantial portion of the light emitted from the LED is along or near the normal, N. Conversely, only a small percentage is emitted sideways. Angle α, the angle of intensity, is equal to 2*θ.

For further details of exemplary prior art LED packages with the bulk of the light intensity emitted near the normal, N, see, for example, the product literature for the XLamp™ 7090 from Cree, Incorporated.

When LED 10 is powered on, heat from LED 10 collects along the bottom surface 15 of bonding pad 16. In general, heat radiates from the bottom of photonic chip 12. Typically, an LED such as LED 10 is driven by approximately 350 mAmps and expends approximately one Watt of power where approximately 90% of the expended power is in the form of heat. Conventional approaches for dissipating heat generated from an LED include active and passive techniques. A conventional active technique includes employing a fan to blow cooler air onto the back surface of LED 10. However, a few of the disadvantages of conventional fan based techniques include their cost, their unaesthetic appearance, and their production of fan noise. One conventional passive technique includes an aluminum block with large aluminum extrusions of fins emanating from an outer edge of a light fixture. Failings of this approach include added cost for materials composing the extrusions, added weight, and limited heat dissipation due to a build up of air pressure resulting from the heated air being trapped by the fins.

### SUMMARY OF THE INVENTION

Among its several aspects, the present invention recognizes the desirability of improved passive heat dissipation techniques for heat generated by powered LEDs.

Some exemplary lighting applications include lighting a horizontal surface, wall washing, back lighting a diffuser, and the like. Each of these lighting applications may have different requirements with respect to brightness levels, lighting patterns, and color uniformity. As multiple LEDs such as LED 10 are arranged to address varied requirements of different lighting applications, the brightness of the collective emitted light and the amount of heat generated per area varies with the arrangement. For example, a particular lighting application may require a high brightness level. To meet the high brightness requirement of the particular lighting application, more LEDs may be arranged closer together in the same predefined area as lighting application requiring less brightness. However, the closer together LEDs are placed, the more heat is generated in the concentrated area containing the LEDs.

Among its several aspects, the present invention recognizes improvements to LED fixtures, in general, in addition to those described in U.S. Ser. No. 11/379,709 filed Apr. 21, 2006 entitled “Light Emitting Diode Packages” which is incorporated by reference in its entirety.

One aspect of the present invention includes a backing of thermally conductive material and an array of LEDs. It is noted that the term “array of LEDs” as used herein means a module of one or more LEDs in various configurations and arrangements. The backing includes a cell structure. The cell structure comprises a plurality of hollow cells contiguously positioned in a side by side manner. The array of LEDs is mounted to a printed circuit board (PCB). The PCBs for the two or more arrays are attached to the cell structure to balance heat dissipation and color uniformity of the LEDs.

Another aspect of the present invention includes a hollow tube and an array of LEDs. In certain embodiments, the hollow tube has a top flat surface. The array of LEDs is mounted to a printed circuit board (PCB). The PCB for the array of LEDs is attached to the top surface of the hollow tube.

Another aspect of the present invention is directed towards light strip for LEDs. The light strip includes a hollow tube and an array of LEDs. The hollow tube has a bottom flat surface, a first open end, and a second open end. The first open end defines an area smaller than the area defined by the second open end to create an air pressure differential within the hollow tube. The array of LEDs is mounted to a printed circuit board (PCB), the PCB for the array of LEDs is attached to the bottom flat surface of the hollow tube.

A more complete understanding of the present invention, as well as other features and advantages of the invention, will be apparent from the following detailed description, the accompanying drawings, and the claims.

### BRIEF DESCRIPTION OF THE DRAWINGS

FIGS. 1A-1C are top and side views illustrating aspects of a prior art LED packaging arrangement, and a graph illustrating how the intensity of light emission tends to vary with the angle from normal, respectively.

FIG. 2 shows a top view of a 1 foot×1 foot LED lighting packages in accordance with the present invention.

FIG. 3 shows a top view of a 1 foot×1 foot LED lighting package having an alternative backing arrangement to FIG. 2 in accordance with the present invention.

FIG. 4 is a perspective view of an embodiment for the backing shown in FIG. 2 in accordance with the present invention.

FIGS. 5A-5F show top views of alternative shapes for a cell shown in FIG. 4 according to the present invention.

FIG. 6 shows a perspective view of backing 210 with a bottom flat panel attached thereon in accordance with the present invention.

FIG. 7 shows a perspective view of a portion of the backing shown in FIG. 6 in accordance with the present invention.

FIG. 8 shows an alternative embodiment for the backing shown in FIG. 3 in accordance with the present invention.

FIG. 9 shows an LED light strip for dissipating heat from a strip of LEDs in accordance with the present invention.

FIG. 10 shows a bottom view of an alternative embodiment for the cell structure shown in FIG. 4 in accordance with the present invention.

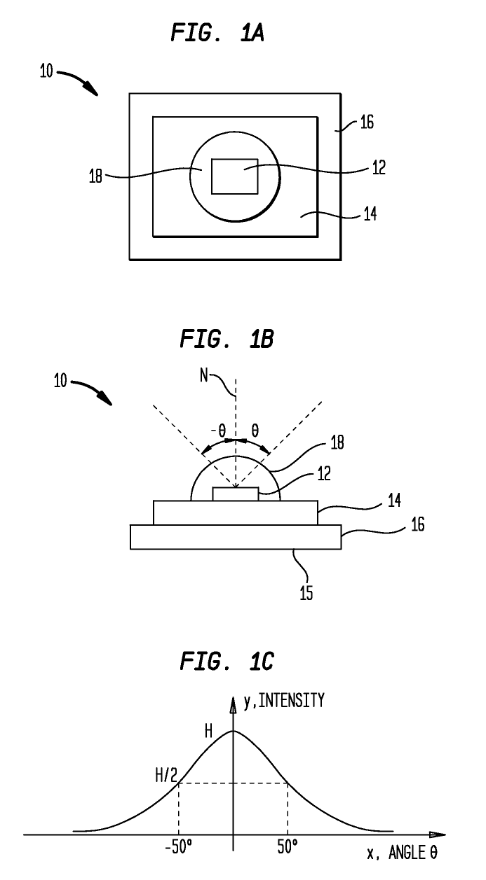

### DETAILED DESCRIPTION

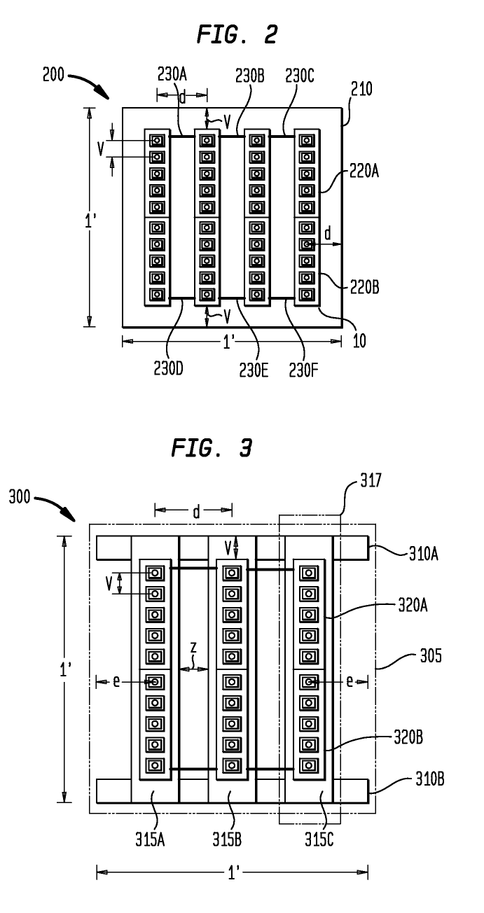

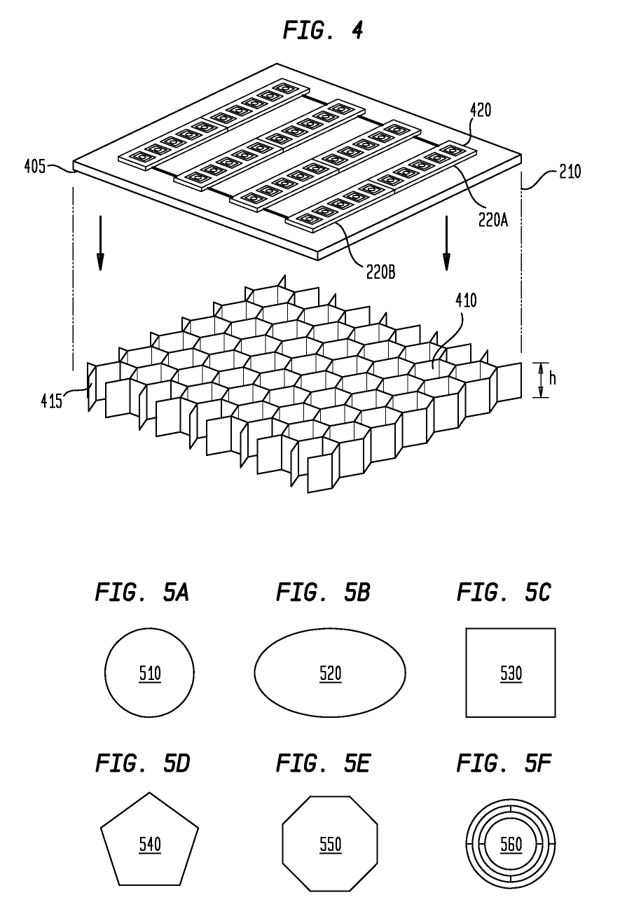

FIG. 2 shows a top view of a 1 foot×1 foot light emitted diode (LED) lighting package 200 in accordance with the present invention. The LED lighting package 200 includes a backing 210 of thermally conductive material such as aluminum. It is recognized that other thermally conductive materials such as ceramics, plastics, and the like may be utilized, aluminum is preferable because of its abundance and relative cheap cost. The construct of backing 210 as shown in FIG. 2 will be described further in connection with the discussion of FIG. 4.

The LED lighting package 200 includes four columns of LEDs. Each column includes two printed circuit boards (PCB) such as PCB 220A and 220B. On each PCB, five LEDs such as LED 10 are mounted and are electrically connected in serial with each other. The total number of LEDs in LED lighting package 200 is forty. Each PCB includes a positive voltage terminal and a negative voltage terminal (not shown). The negative voltage terminal of PCB 220A is electrically connected to the positive voltage terminal of PCB 220B so that the ten LEDs defining a column are electrically connected in serial. It should be recognized that although two PCBs are shown to construct one column of LEDs, a single PCB may be utilized for a particular column of LEDs. Each column of ten LEDs is electrically connected in parallel to its adjacent column over wires 230A-D and are equally spaced at a distance d measured in the horizontal direction from the center of adjacent LEDs. For example, the distance, d, in FIG. 2 is approximately 2.4 inches. In the vertical direction, the LEDs are equally spaced at a distance, v, where v is approximately 1 inch. The backing 210 is preferably anodized white aluminum to reflect the light emitted from the LEDs. When powering LED lighting package 200 under an ambient temperature of approximately 25° C., the temperature of cross members 315A-315C at steady state was approximately 53° C.

As discussed in patent application entitled “LIGHT EMITTING DIODE PACKAGES”, as long as d is closer than a selected distance, color uniformity for the LEDs will be addressed. Other arrangements containing six and eight equally spaced columns of LEDs have also been tested. In the six column arrangement or 60 LEDs, d is approximately 1.7 inches, and the steady state temperature is approximately 62° C. In the eight column arrangement or 80 LEDs, d is approximately 1.33 inches, and the steady state temperature is approximately 74° C.

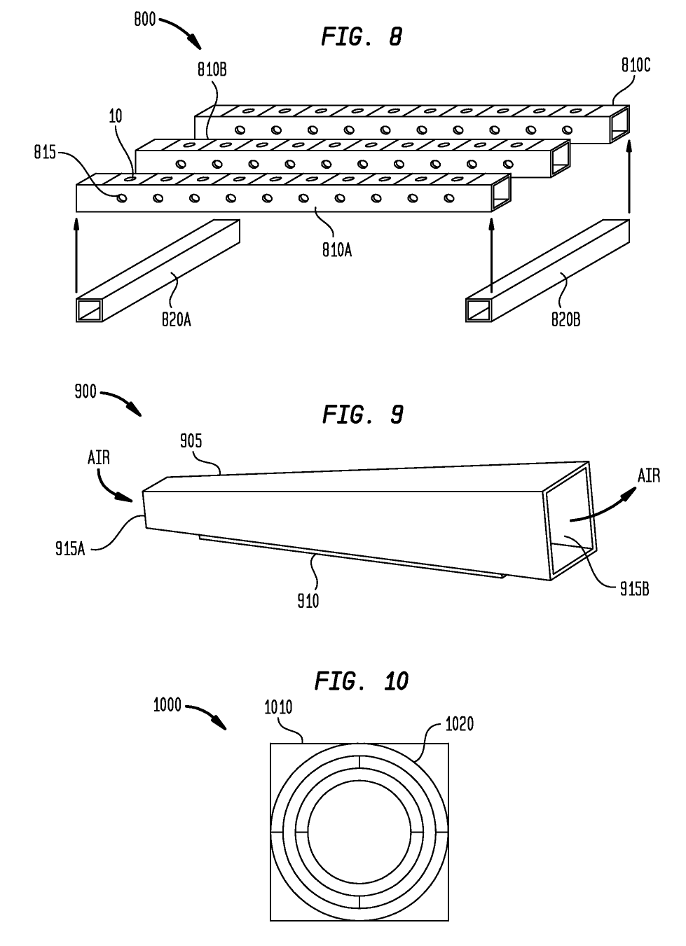

FIG. 3 shows a top view of a 1 foot×1 foot LED lighting package 300 employing an alternative backing arrangement 305 in accordance with the present invention. Backing arrangement 305 is in the form of a ladder structure. Backing arrangement 305 is composed of thermally conductive material such as aluminum and preferably anodized with a white gloss. The ladder structure includes an upper member 310A and a lower member 310B attached to cross members 315A-315C. The combination of cross member 315C with PCBs 320A and 320B compose LED module 317. The cross members 315A-315C as shown in this exemplary embodiment are approximately 1.5 inches wide, 1 foot long, and 1/16 inches thick. Cross members 315A-315C are fixedly attached to members 310A-310B and separated by free space. Although not shown in FIG. 3, cross members 315A-315C contain a cell structure of thermally conductive material and will be described further in connection with the discussion of FIGS. 4-7. Alternatively, each cross member may be mounted to a hollow tube as disclosed in FIGS. 8 and 9. PCBs such as PCBs 320A and 320B containing an array of LEDs are attached to the cross members 315A-315C. The vertical equidistant spacing, v, in this exemplary embodiment is approximately 1 inch. The horizontal equidistant spacing, d, in this exemplary embodiment is approximately 2.75 inches. The edge distance, e, as shown in FIG. 3 is approximately 3¼ inches. With air separating the cross members, it would be expected that heat dissipation would increase allowing the cross members to be arranged in closer proximity for a given heat dissipation level. Placing the cross members closer allows more space in the 1 foot by 1 foot package to add additional LED columns to increase brightness levels.

FIG. 4 is a perspective view of one embodiment for the backing 210 shown in FIG. 2 in accordance with the present invention. Backing 210 includes an aluminum panel 405 fixedly attached to a cell structure 415. Aluminum panel 405 has a thickness of approximately 1/16 inches.

Cell structure 415 has a height, h, of approximately ¼ inch. Cell structure 415 is composed of a plurality of hexagonally shaped hollow cells such as cell 410 contiguously positioned in a side by side manner. Each cell has a diameter of approximately ½ inch. Cell structure 415 has substantially the same length and width dimensions as the aluminum panel 405 so as to align the edges of aluminum panel 405 with the edges of cell structure 415. Aluminum panel 405 may be suitably attached to cell structure 415 utilizing a thermal epoxy such as Loctite® 384. Although aluminum is presently preferred, it is well recognized that other thermally conductive material such as graphite may also be utilized.

When light is emitted from the LEDs such as LEDs 420 affixed to the printed circuit boards (PCBs) such as PCBs 220A and 220B, heat is dissipated through aluminum panel 405 and the surface area of the hexagonally shaped cells.

FIGS. 5A-5E show top views of alternative shapes for cell 410 according to the present invention. FIG. 5A shows a top view of a circular cell 510. FIG. 5B shows a top view of an elliptical cell 520. FIG. 5C shows a top view of a square cell 530. FIG. 5D shows a top view of a pentagonal cell 540. FIG. 5E shows a top view of an octagonal cell 550. It is recognized that other cell shapes may be utilized for cell structure 415. FIG. 5E shows a top view of a cell 560 composed of concentric circles. It is recognized that other cell shapes may be utilized for cell structure 415. The cell shapes of FIG. 5 may be contiguously arranged on a side-by-side basis to form a cell structure suitable for an alternative cell structure 415.

Although the cell structure shown in FIGS. 4 and 5 has a cell diameter of approximately ½ inch, other diameters of cells may be utilized including diameters ranging from ⅛ inch to an inch.

FIG. 6 shows a perspective view of an alternative backing arrangement 600 in accordance with the present invention which may be suitably employed as the backing 210 in FIG. 2. Backing arrangement 600 includes a top flat panel 605 attached to a cell structure 615 in a manner similar to FIG. 4. Optional bottom flat panel 620 is attached to the bottom of cell structure 615. The optional bottom flat panel 620 has substantially the same dimensions as flat panel 605 and is fixedly attached to the cell structure 615. Bottom flat panel 620 may be employed to address lighting applications requiring a flat surface in back of a lighting package such as display models where the bottom flat panel 620 of a lighting package such as lighting package 300 is utilized when mounting the lighting package to a wall.

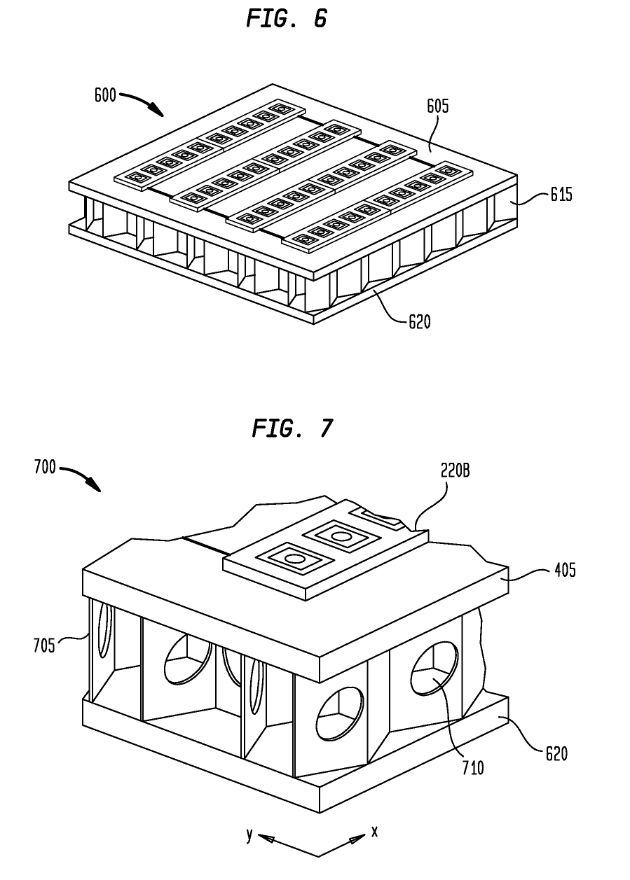

FIG. 7 shows a perspective view of a portion of an alternative backing 700 in accordance with the present invention. In backing 700, cell structure 705 has a height, h, of approximately ¼ inch. Cell structure 705 is composed of a plurality of hexagonally shaped hollow cells. Cell structure 705 includes a series of ten bores drilled in both the x and y direction transverse to the hexagonally shaped hollow cells. Each bore such as bore 710 has approximately a ⅛ inch diameter. The separation between adjacent bores is approximately 1 inches on center. It is recognized the number of bores which are drilled are dependent on the diameter of each bore. Consequently, more bores may be drilled that have smaller diameters. Additionally, it is recognized that varied diameters of bores may alternatively be utilized.

FIG. 8 shows an alternative backing 800 in accordance with the present invention suitable for use as backing such as backing 305 shown in FIG. 3. Backing 800 includes three cross bars 810A-810C and two frame bars 820A-820B made from a thermally conductive material. For the sake of simplicity, only cross bar 810A will be described in detail here, but cross bars 810B-810C may suitably be similar to cross bar 810A. Cross bar 810A is a hollow bar approximately 1 foot long having a 1 inch×1 inch square face and is preferably made of anodized black aluminum. One or more PCBs containing a total of ten LEDs such as LED 10 are mounted on the top surface of cross bar 810A. Ten bores such as bore 815 are drilled along the lateral surfaces of cross bar 810A. Frame bars 820A-820B are hollow bars approximately 12 inches long having a 1 inch×1 inch square face. Frame bars 820A-820B are mounted to the bottom surfaces of cross bars 810A-810C. The cross bars 810A-810C are equally space on center on frame bars 820A-820B such that the center of cross bar 810A is approximately 2¼ inches from the front edge of frame bars 820A-820B, cross bar 810B is approximately 4½ inches from the front edge of frame bars 820A-820B, and cross bar 810C is approximately 6¾ inches from the front edge of frame bars 820A-820B.

FIG. 9 shows an LED light strip 900 for dissipating heat from a strip of LEDs in accordance with the present invention. LED light strip 900 includes a strip of LEDs 910 mounted on the bottom surface of hollow tube 905. Hollow tube 905 has two open ends 915A-915B. Open end 915A defines a 1 inch×1 inch square entrance to hollow tube 905. Open end 915B defines a 1 inch×1.5 inches rectangular exit to hollow tube 905. The difference in sizes of the two open ends 915A-915B creates air pressure differential within the hollow tube 905. The difference in sizes of the two open ends 915A-915B allows ambient air to flow into to hollow tube 905 at opening end 915A and air heated by the strip of LEDs 910 to exit from hollow tube 905 at opening end 915B. LED light strip 900 may be mounted on a ceiling or on furniture and is typically used to light a surface such as a desk, table, and the like. The hollow tube is preferably a black anodized length of aluminum.

While the LED lighting packages have been disclosed in the context of an XLamp™ 7090 from Cree, Incorporated, the dimensions disclosed within a package may vary based on the operating characteristics of a particular LED such as the XLamp™ 3 7090, XLamp™ 4550, and the like when employed by the LED lighting packages.

Although the cell structure described above is disclosed as have a plurality of individual cells, the present invention contemplates various other arrangements such as a series of cells within cells such as a series of concentric circles which expand to the size of the area enclosed the arrangement of LEDs. FIG. 10 shows a bottom view of an alternative embodiment 1000 for the cell structure shown in FIG. 4 in accordance with the present invention. The alternative embodiment 1000 includes a series of concentric circles 1020 made from thermally conductive material such as aluminum, graphite and the like attached to the bottom surface of printed circuit board 1010. PCB 1010 includes one or more LEDs (not shown) mounted on its top surface. The series of concentric circles may have a height in various ranges. Preferably, the height will be in the range of ⅛ inch to an inch. Alternatively, a planar sheet of thermally conductive material may be interposed between the series of concentric circles 1020 and the PCB 1010.

It should be noted array of LEDs is described as mounted to a printed circuit board. Other mounting arrangements are possible so long as the backing is thermally coupled to the LED array. It should also be noted that the printed circuit boards (PCBs) containing one or more LEDs described in the above embodiments is preferably mounted to thermally conductive material utilizing a thermal epoxy such as such as Loctite® 384, other well known techniques including utilizing screws, rivets, and the like are also contemplated by the present invention. Also, the PCBs described above may be painted white to help reflect emitted light or black to help heat dissipation depending on the particular lighting application.

An LED module which includes PCB and LED combination mounted on a thermally conductive backing such as LED module 317 is modular and may be arranged to address various configurations according to a specific lighting application. Depending on the embodiment, the LED lighting packages may include LED modules and/or support members without LEDs. In certain embodiments, the LED modules or support members have been described as strips, alternative shapes and/or lengths for the LED modules may be utilized in accordance with the present invention. For example, LED modules arranged in concentric circles may be utilized to address a spot light lighting application.

While the present invention has been disclosed in the context of various aspects of presently preferred embodiments including specific package dimensions, it will be recognized that the invention may be suitably applied to other environments including different package dimensions and LED module arrangements consistent with the claims which follow.

I claim:

1. A lighting package comprising:
a panel of thermally conductive material comprising a planar sheet having a top surface and a bottom surface;
a cell structure of thermally conductive material, the cell structure comprising a plurality of hollow cells contiguously positioned in a side by side manner, wherein the cell structure is attached to the bottom surface of the panel to form a backing having an open bottom allowing free air flow away from the panel through the hollow cells; and
at least one LED thermally coupled to the top surface of said panel so that heat is dissipated by the backing when light is emitted by the at least one LED.

2. The package of claim 1 wherein the at least one LED is mounted to a top surface of a printed circuit board (PCB) having a bottom surface mounted on said panel utilizing a thermal epoxy.

3. The package of claim 2 wherein the planar sheet is anodized with a white gloss.

4. The package of claim 1 wherein each hollow cell is in the shape of a hexagonal cell.

5. The package of claim 1 wherein each hollow cell is in the shape of an octagonal cell.

6. The package of claim 1 wherein the panel is made from aluminum.

7. The package of claim 6 wherein the cell structure is made from aluminum.

8. The package of claim 1 wherein the cell structure has a plurality of bores transverse to the plurality of hollow cells.

9. The package of claim 8 wherein the backing includes a second planar sheet attached to a bottom surface of the cell structure, the plurality of bores providing for air flow away from the at least one LED.

10. The package of claim 1 wherein the package has a dimension of 1 foot by 1 foot.

11. The package of claim 2 wherein the planar sheet is aluminum and has a thickness of approximately 1/16 inch.

12. The package of claim 1 wherein the cell structure has a height of approximately ¼ inch.

13. The package of claim 11 wherein each hollow cell has a diameter of approximately ½ inch.

14. The package of claim 12 wherein each hollow cell has a diameter between ⅛ inch and 1 inch.

15. The package of claim 1 wherein the at least one LED comprises an array of at least three columns of LEDs with LEDs in different columns spaced by at least a center to center distance of 2.4 inches.

16. The package of claim 15 wherein LEDs in each of the three columns are vertically spaced by at least a center to center distance of 1 inch.

17. The package of claim 1 comprising a ladder structure of plural panels, cell structures, and plural LEDs arranged in arrays.

18. The package of claim 17 wherein the ladder structure further comprises aluminum cross members.

19. The package of claim 18 wherein the cross members are approximately 1.5 inches wide, and 1/16 inch thick.

20. The package of claim 1 wherein the at least one LED is part of an array of LEDs in which each LED is powered with a current of at least 35° mA and the ambient temperature is 25° C.
